(19) United States
(12) Patent Application Publication
(10) Pub. No.: US 2006/0211210 A1
(43) Pub. Date: Sep. 21, 2006

(54) Material for selective deposition and etching

(75) Inventors: Ishwara Bhat, Clifton Park, NY (US); Joseph Seiler, Bernville, PA (US); Canhua Li, Troy, NY (US)

Correspondence Address: WOLF GREENFIELD & SACKS, PC, FEDERAL RESERVE PLAZA, 600 ATLANTIC AVENUE, BOSTON, MA, 02210-2206, US

(73) Assignee: RENSSELAER POLYTECHNIC INSTITUTE, Troy, NY (US)

(21) Appl. No.: 11/215,185

(22) Filed: Aug. 29, 2005

Related U.S. Application Data
(60) Provisional application No. 60/604,920, filed on Aug. 27, 2004.

(51) Int. Cl. H01L 21/331

(52) U.S. Cl. 438/377; 438/369

(57) ABSTRACT

A method of selectively growing silicon carbide is provided. The method includes forming a mask including tantalum carbide that masks a portion of a substrate, and epitaxially growing a crystal including silicon carbide seeded by an exposed surface of the substrate. A method of selectively etching silicon carbide is also provided. The method includes forming a mask including tantalum carbide that masks a portion of a substrate, and etching an exposed surface of the substrate. A method of fabricating a device is further provided that includes forming a mask including tantalum carbide that masks a portion of a first layer of the device, and epitaxially growing a second layer of the device, wherein the second layer includes a crystal including silicon carbide seeded by an exposed surface of the first layer.

### RELATED APPLICATIONS

This application claims priority under 35 U.S.C. § 119(e) to U.S. Provisional Application Ser. No. 60/604,920, entitled “A High Temperature Material for the Selective Deposition and Selective Etching of Silicon Carbide,” filed on Aug. 27, 2004, which is herein incorporated by reference in its entirety.

### FIELD OF INVENTION

The invention relates generally to selective epitaxial growth and/or etching, as well as related devices and methods, and, more particularly to high temperature mask materials for selective epitaxial growth and/or etching.

### BACKGROUND OF INVENTION

Selective epitaxial growth (SEG) of semiconductors has attracted interest in both scientific and industrial circles. With regards to applied science, since SEG is sensitive to deposition chemistries and reaction kinetics, experiments involving SEG can provide insights into the details of deposition processes. In industry, SEG is often employed to enable the production of novel device structures which might otherwise be difficult to fabricate using non-selective deposition techniques. For example, SEG is widely used in the fabrication of raised source-drain field effect transistors (FET) and selective epitaxial base silicon germanium heterojunction bipolar transistors (HBT).

### SUMMARY OF INVENTION

Embodiments of the invention provide methods for selective epitaxial growth and etching, as well as related devices and methods.

In one embodiment, a method of selectively growing silicon carbide is provided. The method comprises forming a mask comprising tantalum carbide that masks a portion of a substrate comprising silicon carbide to leave an exposed surface of the substrate. The method also comprises epitaxially growing a crystal comprising silicon carbide seeded by the exposed surface of the substrate.

In one embodiment, a method of selectively etching silicon carbide is provided. The method comprises forming a mask comprising tantalum carbide that masks a portion of a substrate comprising silicon carbide to leave an exposed surface of the substrate. The method further comprises etching the exposed surface of the substrate at a temperature above about 1200° C.

In one embodiment, a method of fabricating a device is provided. The method comprises forming a mask comprising tantalum carbide that masks a portion of a first layer of the device to leave an exposed surface of the first layer. The method further comprises epitaxially growing a second layer of the device. The second layer comprises a crystal comprising silicon carbide seeded by the exposed surface of the first layer.

### BRIEF DESCRIPTION OF DRAWINGS

In the drawings, each identical or nearly identical component that is illustrated in various figures is represented by a like numeral. For purposes of clarity, not every component may be labeled in every drawing. In the drawings:

FIG. 1 is a flowchart illustrating a method of performing selective epitaxial growth and/or epitaxial layer overgrowth in accordance with some embodiment of the invention;

FIGS. 2(a)-(e) are schematic illustrations of structures that may be formed as a result of performing one or more steps of the method illustrated in FIG. 1 in accordance with some embodiments of the invention;

FIG. 3 is a flowchart illustrating a method of performing selective etching in accordance with some embodiment of the invention;

FIG. 4(a)-(c) are schematic illustrations of structures that may be formed as a result of performing one or more steps of the method illustrated in FIG. 3 in accordance with some embodiments of the invention;

FIG. 5 is a schematic illustration of a p-n diode device in accordance with one embodiment of the invention;

FIG. 6 is a graph of current density versus forward voltage for an illustrative working example of a SiC p-n junction diode at various temperatures in accordance with one embodiment of the invention;

FIG. 7 is a graph of current density versus reverse voltage for an illustrative working example of a SiC p-n junction diode at various temperatures in accordance with one embodiment of the invention;

FIG. 8(a)-(c) are scanning electron microscopy views of illustrative working examples of SiC selectively grown using a TaC mask in accordance with one embodiment of the invention;

FIG. 9(a)-(c) are large-scale scanning electron microscopy views of illustrative working examples of SiC selectively grown using a TaC mask in accordance with one embodiment of the invention;

FIG. 10 is a graph of a percentage of a mask opening occupied by a (0001) facet as a function of mask opening orientation for illustrative working examples in accordance with one embodiment of the invention; and

FIG. 11(a)-(c) are scanning electron microscopy views of illustrative working examples of SiC selectively etched using a TaC mask in accordance with one embodiment of the invention.

### DETAILED DESCRIPTION

SEG involves the selective growth of a semiconductor on an exposed surface of a substrate using a mask layer having one or more openings. To avoid deposition of semiconductor material on the mask, the mask material is chosen so that growth using specific deposition conditions (e.g., deposition reactants, pressure, and/or temperature) does not occur on the mask surface, but does occur on the exposed surface of the substrate.

A related application of SEG is the enablement of epitaxial lateral overgrowth (ELO). In such a process, a semiconductor is selectively deposited on the exposed surface of the substrate, and deposition continues so as to fill the entire depth of the mask openings. Growth of the semiconductor region then proceeds laterally (and vertically) so as to form a lateral overgrowth region over the mask.

SEG of silicon (Si) and gallium nitride (GaN) has been widely demonstrated with silicon dioxide (SiO₂) and silicon nitride (Si₃N₄) masks, but a scarce amount of SEG has been performed for silicon carbide (SiC) and related materials. Materials such as SiC-based semiconductors are typically deposited at high growth temperatures (e.g., above about 1450° C.) so as to enable the growth of high-quality epilayers using chemical vapor deposition. As a result, identifying a proper mask for the SEG of SiC at these high growth temperatures possess a significant challenge, since the mask must not only withstand high temperatures, but also possess the proper selectively to ensure SEG.

Although SiC can be grown at relatively low temperature (e.g., less than about 1000° C.) via selective deposition of 3C—SiC on a Si substrate using a SiO₂ mask, the oxide mask only serves as a suitable mask for temperatures lower than about 1000° C. due to the presence of appreciable SiO₂ viscous flow for temperatures greater than about 1000° C. Alternatively, SEG of SiC on SiC substrates can be performed using graphite masks and growth temperatures ranging from about 1500° C. to about 1700° C. Additionally, SEG of 4H—SiC, on off-axis (0001) and (1120) SiC substrates, can also be accomplished using a carbon mask and growth temperatures of about 1500° C.

Although SEG and ELO of SiC can be performed using a carbon mask (e.g., graphite), the carbon mask may act as a carbon source during high temperature SiC epitaxial growth. This effect can cause significant local variation in the Si/C ratio which may be detrimental to device reliability and performance. Additionally, polycrystalline SiC deposition can occur on carbon masks, which can in turn degrade selectivity and interfere with ELO.

Some materials, according to embodiments of the invention, can provide improved masks. One such material is tantalum carbide (TaC). TaC, for example, can enable selective epitaxial growth and epitaxial lateral overgrowth of SiC materials at high growth temperatures. The growth behavior will be affected by deposition parameters, including growth temperature and reactant (e.g., silane, propane) flows. The TaC mask can also be used for the selective etching of SiC materials at high temperatures.

According to some embodiments of the invention, a TaC mask can solve problems encountered with some prior masks. TaC is stable up to temperatures at least as high as 1600° C., and substantially no polycrystalline SiC deposition takes place on the mask. As a result, SiC can be selectively grown on SiC substrates using a TaC mask at temperatures greater than about 1200° C. (e.g., greater than about 1300° C., greater than about 1400° C., greater than about 1500° C.). Additionally, SiC can be selectively etched using a TaC mask, and in some embodiments, the etching can be performed at temperatures greater than about 1200° C. (e.g., greater than about 1300° C., greater than about 1400° C., greater than about 1500° C.).

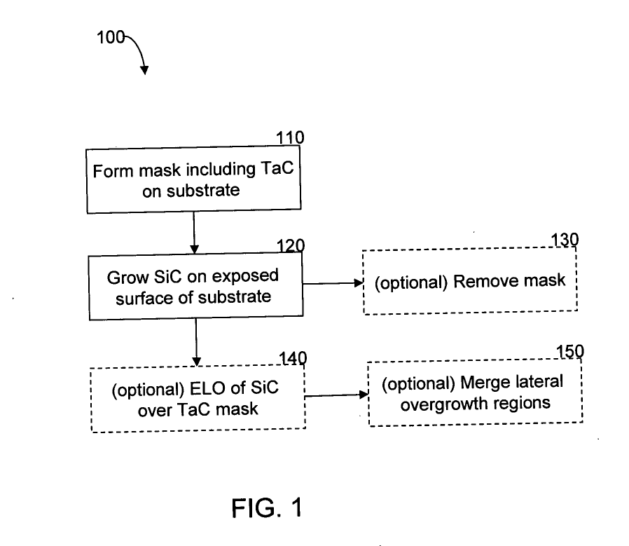

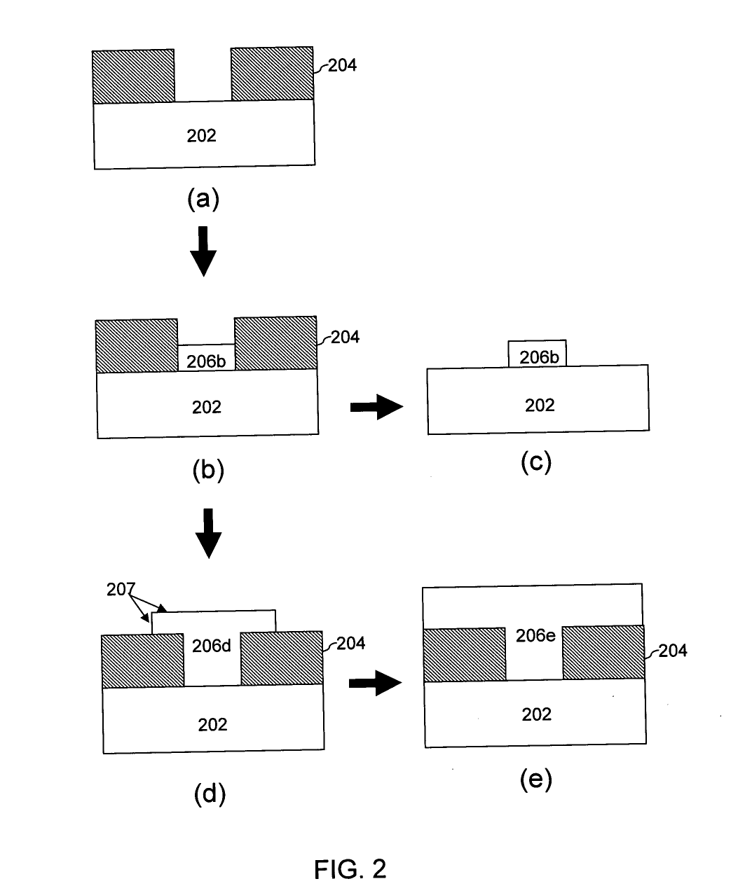

FIG. 1 illustrates a method 100 of performing SEG and/or ELO according to some embodiments of the invention. FIGS. 2(a)-(e) illustrate representative (intermediate) structures that may be formed as a result of performing the steps of method 100.

The method begins with the formation of a suitable mask 204 on a substrate 202 (step 110). The substrate 202 may comprise of any suitable material and, although not illustrated in FIG. 2(a), the substrate can comprise of any number of layers of materials and/or portions of layers, as the invention is not limited in this respect. In some embodiments, the substrate may comprise a SiC wafer (e.g., on-cut or off-cut at any suitable angle). For example, the substrate may be a 4H—SiC(1000) wafer having a 8° miscut towards the <1120> direction. In some embodiments, the substrate may include doped layers including highly doped (P+ or N+) layers, epilayers, and/or any other suitable layers.

As shown in FIG. 2(a), the mask 204 may be patterned with one or more openings so as to expose portions of the surface of the underlying substrate 202. The mask can include TaC and may be formed using any suitable technique.

In one approach, a mask including TaC may be formed by depositing a layer of tantalum (Ta) on the substrate. The Ta may be deposited using any suitable technique (e.g., evaporation) and may be patterned using any patterning process (e.g., photo-lithography, nano-imprint patterning). The Ta layer may be converted to TaC by annealing in the presence of reactants that react with the Ta and form TaC. For example, the Ta may be annealed at about 1300° C. in the presence of propane and hydrogen (e.g., 1.5×10⁻⁴ mole fraction of propane in hydrogen) for about 30 minutes so as to convert the Ta to TaC. In another approach, the Ta layer may be converted to TaC prior to performing the patterning process that forms openings in the mask 204. It should be understood that these are just some examples of methods for forming masks including TaC and the invention is not limited in this respect.

The method 100 proceeds with the selective epitaxial growth of semiconductor material comprising SiC on the exposed surface of the substrate 202 (step 120). In some embodiments, the selective epitaxial of SiC using a TaC mask may be achieved using chemical vapor deposition (CVD) at temperatures greater than about 1200° C. (e.g., greater than about 1300° C., greater than about 1400° C., greater than about 1500° C.). For example, SiC may be selectively grown using a TaC mask in a horizontal, rf-heated cold wall reactor at temperatures of about 1450° C. to about 1550° C. and flow rates of about 1.2 sccm, about 0.6 sccm to about 1.5 sccm, and 9 slm of propane (C3H8), silane (SiH4), and hydrogen (H2), respectively. Under these conditions and at a total reactor pressure of 100 torr, selective SiC epilayers can be grown with planar growth rates of about 3 μm/hour to about 4 μpm/hour.

FIG. 2(b) illustrates a structure that may result from performing step 120 of method 100. A selective epilayer 206b comprising SiC may be seeded by the exposed surface of substrate 202, and a mask 204 comprising TaC can suppress the deposition of semiconductor material on the mask surface. Although the illustration of FIG. 2(b) shows the epilayer 206b as a layer with uniform thickness, it should be appreciated that the epilayer may comprise one or more facets. The orientation of the sides of the mask opening with respect to the substrate crystal directions may determine the epilayer facets that from during selective deposition, as shall be discussed later.

After a desired thickness of the epilayer 206b is attained, growth may be terminated, and the mask 204 may be optionally removed so as to leave behind the epilayer 206b over the substrate 202 (step 130), as illustrated in FIG. 2(c). Masks including TaC may be removed via etching with solutions comprising a suitable oxidizing agent and a oxide removing agent. In one embodiment, a TaC mask may be etched using a wet solution including nitric acid (HNO₃), hydrofluoric acid (HF), and an optional diluting agent (e.g., water, acetic acid). The wet solution can comprise a 1:1:1 mixture of HNO₃:HF:H₂O, but it should be understood that any other suitable ratios of constituents may be used as an etching solution.

Optionally, selective epitaxy may continue so as to grow the epilayer to a thickness greater than the depth of the mask opening. In doing so, ELO may result, wherein the epilayer can grow laterally along the mask surface (step 140). As illustrated in FIG. 2(d), epilayer 206d may grow laterally along the mask 204, where the lateral growth rate may differ from the vertical growth rate. Differences in lateral and vertical growth rates may be the result of the variations in growth rate for different crystal surfaces of the semiconductor being deposited. Furthermore, although the illustration of FIG. 2(d) shows the laterally overgrown epilayer 206d as having rectangular facets, it should be appreciated that the facets may depend on the orientation of the sides of the mask openings with respect to the substrate crystal directions.

Optionally, ELO may be continued so as to merge the lateral overgrowth regions from multiple openings in the mask 204 (step 150). In one embodiment, the lateral overgrowth of the epilayer 206e may continue until a desired surface area of the mask 204 has been covered, as shown in FIG. 2(e).

In further embodiments, other semiconductor materials may be deposited on the epilayer after any one of the steps of method 100. For example, after step 120, 130, 140 and/or 150, an epilayer including gallium nitride (GaN) may be deposited on an epilayer comprising SiC. In should also be appreciated that other variations are possible, and any number of other semiconductors may also be deposited over the selectively deposited epilayers. Moreover, it should also be understood that the selectively grown epilayer and any other deposited layers can be in situ doped during growth, so as to form doped semiconductor structures. This doping technique may be used in conjunction with (or as an alternative to) one or more ex situ doping techniques, such as ion implantation.

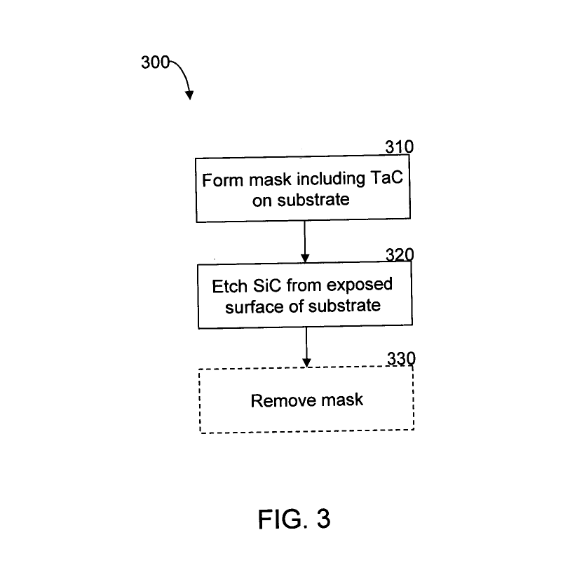

FIG. 3 illustrates a method 300 of performing selective etching according to some embodiments of the invention. FIGS. 3(a)-(c) illustrate representative (intermediate) structures that may be formed as a result of performing the steps of method 300.

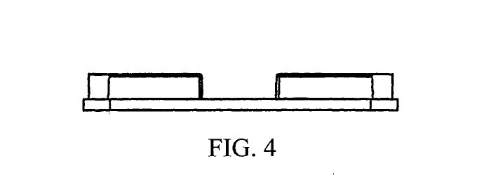

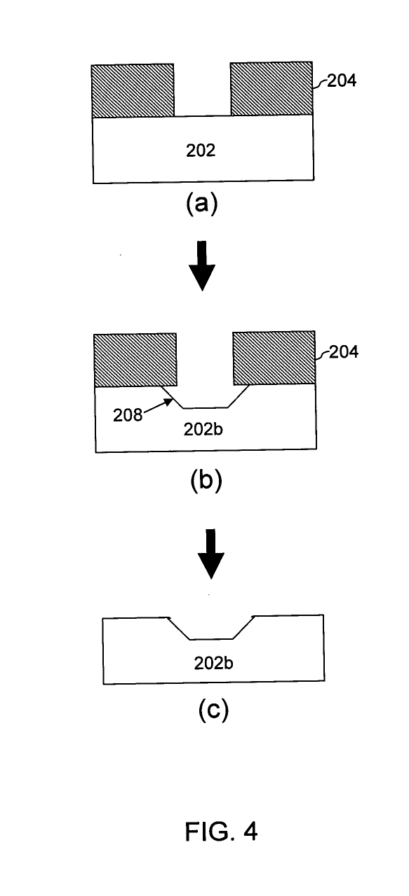

The method begins with the formation of a suitable mask 204 on a substrate 202 (step 310), as previously described in connection with method 100. As shown in FIG. 4(a), the mask 204 may be patterned with one or more openings so as to expose portions of the surface of the underlying substrate 202. As previously noted, the mask can include TaC and may be formed using any suitable technique.

As previously noted, the substrate 202 may comprise of any suitable material and, although not illustrated in FIG. 2(a), the substrate can comprise of any number of layers of materials and/or portions of layers, as the invention is not limited in this respect. In some embodiments, the substrate may comprise a SiC wafer (e.g., on-cut or off-cut at any suitable angle). For example, the substrate may be a 4H—SiC(1000) wafer having a 8° miscut towards the <1120> direction. In some embodiments, the substrate may include doped layers including highly doped (P+ or N+) layers, epilayers, and/or any other suitable layers.

The method 300 proceeds with the selective etching of the exposed surface of the substrate 202 (step 320), as illustrated in FIG. 4(b). The etching may be performed at high temperatures using a suitable chemistry. In one embodiment, selective etching of a surface is performed at temperatures greater than about 1200° C. (e.g., greater than about 1300° C., greater than about 1400° C., greater than about 1500° C.). For example, a SiC surface may be selectively etched at a temperature greater than about 1200° C. in the presence of suitable concentrations of reactant gas.

In one embodiment, selective etching may be performed in a horizontal, low pressure, cold wall CVD reactor. A gas mixture including C₃H₈, SiH₄ and H₂ may be used, with flow rates of about 0 sccm to about 2.4 sccm, about 0.6 sccm to about 1.5 sccm, and about 9 slm, respectively. The reactor pressure may be in the range of about 50 torr to about 200 torr, with sample temperature maintained between about 1450° C. and about 1600° C.

As shown in FIG. 4(b), the etched substrate 202b may have etch facets 208 which may be determined by the orientation of the sides of the mask opening with respect to the substrate crystal directions. In addition, the vertical and lateral etch rates may vary as a result of differing etch rates for different crystal surfaces of the substrate 202b. Furthermore, the etching process may involve undercut etching beneath the mask 204.

Optionally, after the etching process is complete, the mask 204 may be removed (step 330), leaving behind the etched substrate 202b, as illustrated in FIG. 2(c). As previously described, masks including TaC may be removed via etching using solutions comprising an oxidizing agent and a oxide removing agent. In one embodiment, a TaC mask may be etched using a wet solution including nitric acid (HNO₃), hydrofluoric acid (HF), and an optional diluting agent (e.g., water).

Moreover, the etched substrate 202b (with or without the mask 204) may be used as a starting structure for additional processing steps. In some embodiments, the etched substrate 202b (with or without the mask 204) may be used as a starting structure for selective epitaxial growth of desired layers (e.g., doped and/or undoped layers including SiC).

It should also be appreciated that any number of the aforementioned structures, both intermediate and/or final, can be used in the fabrication of semiconductor devices, including electronic, optoelectronic and optical devices.

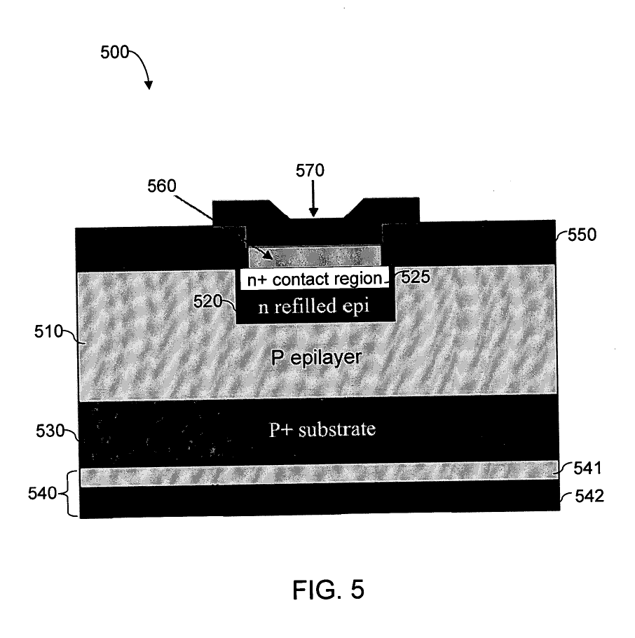

FIG. 5 illustrates a p-n diode device 500 in accordance with one embodiment of the invention. In some embodiments, the p-n diode may be fabricated using selective epitaxy with a mask comprising TaC. In some embodiments, the p-n diode device 500 comprises SiC semiconductor materials.

The device 500 includes a P-doped epilayer region 510 and an n-doped epilayer region 520 which together form the p-n junction of the device 500. The P-doped epilayer is disposed over a P+ doped substrate 530 having one or more backside contact layers 540. For example, in the illustrative embodiment of FIG. 5, the backside contact layers include an Al/Ni/Al layer stack 541 disposed over a Ti and/or Mo contact layer 542. An n+ contact region 525 may be formed over the n-doped epilayer region 520, and may facilitate the formation of an ohmic contact during device operation. An insulating layer 550 having an opening over the p-n junction region may be formed on one or more sides of the p-n junction region. The insulating layer 550 may be formed of silicon dioxide (SiO₂), silicon nitride (Si₃N₄), combinations thereof, and/or any other suitable insulating material. A contact stack 560 may be present over the n+ contact region, and can be formed of any conducting material. For example, the contact stack 560 may include an ohmic Ti/Ni/Al stack. An interconnect (and/or contact pad) 570 may also be present in contact with the contact stack 560, and may be formed of any suitable conducting material, for example, layer 570 can comprise Ti and/or Mo.

In some embodiments, the n-doped epilayer region 520, the P-doped epilayer 510, and/or the P+substrate 530 can include one or more materials comprising SiC. In some embodiments, one or more epilayers may be selectively grown using a TaC mask, which can be removed after the growth process. For example, the n-doped epilayer region 520 may be selectively grown using a TaC mask over an etched substrate region. In this way, an n-doped region may be selectively deposited in an etched substrate hole, thereby forming a recessed p-n junction diode.

In one embodiment, a starting wafer comprising of a p-doped epilayer 510 on a P+ substrate 530 may be used. For example, the starting wafer can be an 8° off-cut (0001) Si-face, p-on-p+ 4H—SiC wafer. The p-doped epilayer 510 can be an Al-doped SiC epilayer with a thickness of about 12 μm with a doping concentration of about 9×10⁻¹⁵ cm⁻³. A Ta layer can be deposited over the starting wafer to a form a layer having a suitable thickness (e.g., greater than 50 nm, greater than 70 nm, greater than 100 nm) and can be patterned to form openings for the p-n diode regions. Patterning can be accomplished using photolithography and/or any other patterning technique. The Ta and underlying SiC epilayer may be etched using one or more etches (e.g., reactive ion etching (RIE)) so as to form openings in the Ta and trenches in the underlying SiC epilayer. For example, a single RIE etch using a CHF₃/0₂ plasma can be used to etch the regions for the p-n diodes. The p-doped epilayer 510 may be etched to a suitable depth (e.g., greater than 0.5 μm, greater than 1.0 μm, greater than 1.5 μm) so as to form a trench which shall be selectively refilled with n-doped epitaxial material, thereby forming the p-n junction region.

The Ta layer can be converted to a TaC mask using any suitable conversion process. For example, the Ta may be converted to TaC by exposing the wafer to an ambient having about 150 ppm propane in hydrogen at a temperature of about 1300° C. for times greater than about 10 minutes (e.g., greater than 15 minutes, greater than 30 minutes).

In some embodiment, selective epitaxial growth of a n-doped region 520 comprising SiC is performed using CVD at temperatures greater than about 1200° C. (e.g., greater than about 1300° C., greater than about 1400° C., greater than about 1500° C.). In one embodiment, the selective epitaxial growth temperature of the n-doped region 520 comprising SiC is within the range of about 1500° C. to about 1600° C., the growth pressure is about 80 torr, and SiH₄, C3H8, and N₂ are used as precursors in a H₂ carrier gas, with flow rates of about 2.2 sccm, about 3.7 sccm, about 8 sccm, and about 12.5 slm, respectively. The n-doped region 520 can be doped in situ using the nitrogen precursor so as to attain suitable dopant concentrations during selective epitaxial growth. In other embodiments, the doping may be introduced ex situ using ion implantation, and/or using other doping techniques, as the invention is not limited in this respect.

The TaC mask used for the SEG may then be removed. For example, the TaC mask may be removed using a wet etch in a solution comprising HNO₃, HF and water, as previously described.

After the TaC mask has been removed, the remainder of the p-n diode structure may be formed. For example, the insulating layer 550 (e.g., SiO₂) may be deposited over the surface of the wafer and patterned so as to provide an opening over the p-n junction region. A shallow implant may then be performed to form the n+ contact region 525 in the topmost region of the n-doped epitaxial region 520. For example, a shallow phosphorus implantation using five successive implants with varying energies and a total dose of about 4×10¹⁵ atoms/cm³ can be used to form the n+ contact region 525. A contact stack 560 (e.g., Ti/Ni/Al stack) contacting the n+ contact region 525 can then be formed using a lift-off technique. Furthermore, the backside of the wafer may be processed so as to form a back-side contact. For example, an Al/Ni/Al stack 541 can be deposited on the wafer backside so to form a large-area backside contact with the P+ substrate 530. The wafer can then be heated to about 1050° C. so as to anneal the contact metals (e.g., the Ti/Ni/Al and Al/Ni/Al stacks).

Interconnect (and/or contact pad) 570 can then be deposited and patterned on the surface of the wafer, and a contact layer 542 may be deposited on the backside of the wafer. The interconnect layer (and/or contact pad) and the backside contact layer may be formed of a suitable material to facilitate contacting with contact probes. For example, the interconnect layer (and/or contact pad) and the backside contact layer may be formed of Ti and Mo.

Although the above illustrative embodiment is directed towards p-n junction diodes, selective epitaxy using a mask comprising TaC may also be used to fabricate other devices, including bipolar transistors comprising either p-n-p or n-p-n doped structures. For example, bipolar transistors may be formed of one or more semiconductor materials including SiC.

In some embodiments, devices (e.g., diodes, bipolars, FETs) comprising SiC may be operable at high temperatures and voltages due to the large bandgap (e.g., about 3 eV), a high avalanche electric breakdown field (e.g., about 2×10⁶ V/cm) and a high thermal conductively (e.g., about 3 to 4 Wcm⁻¹K⁻¹) of SiC. Such devices may also possess low leakage currents (even at high temperatures).

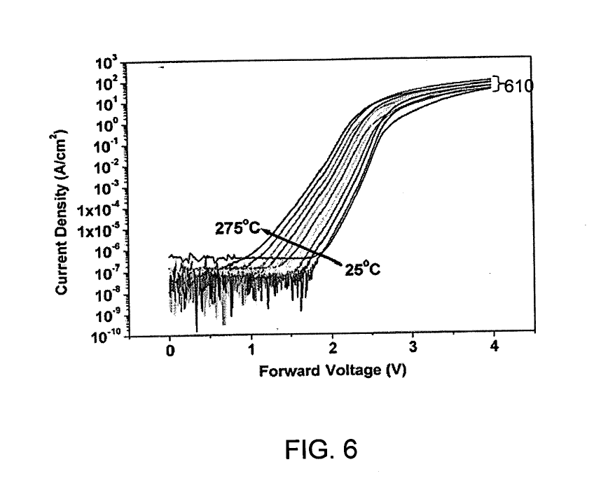

FIG. 6 is a current density versus forward voltage graph for an illustrative working example of a 4H—SiC p-n SiC diode fabricated using the above-mentioned selective epitaxial process with a TaC mask, in accordance with one embodiment of the invention. Curves 610 illustrate the forward current-voltage characteristics at various temperatures ranging from about 25° C. to about 275° C. The ideality factor is about 1.94-2.08 in the above-mentioned temperature range. The p-n SiC diode possesses a low reverse leakage current (e.g., lower than about 4.0×10⁻⁷) up to reverse voltages of about 100 V. For example, at room-temperature, the leakage current density at about 10 V reverse voltage is about 1.6×10⁻⁷ A/cm², the leakage current density at about 50 V reverse voltage is about 2.3×10⁻⁷ A/cm², and the leakage current density at about 100 V reverse voltage is about 3.5×10⁻⁷ A/cm².

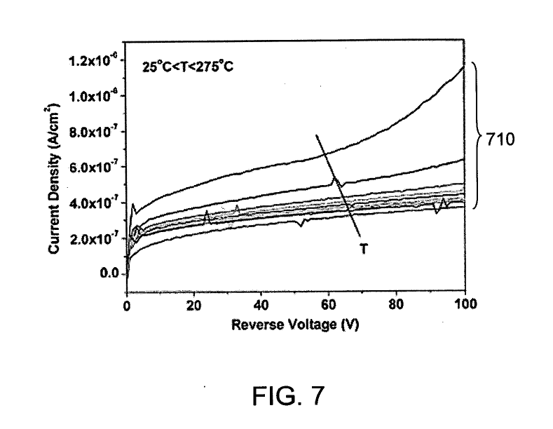

FIG. 7 is a current density versus reverse voltage graph for an illustrative working example of a 4H—SiC p-n SiC diode fabricated using the above-mentioned selective epitaxial process with a TaC mask, in accordance with one embodiment of the invention. Curves 710 illustrate the reverse current-voltage characteristics at temperatures ranging from about 25° C. to about 275° C. The curves 710 show little change in leakage current up to temperatures of about 275° C., indicating that fewer thermally active generating centers are present in the above diodes as compared to prior SiC p-n junction diodes fabricated by ion implantation without selective epitaxy. The reverse leakage current at temperatures of about 275° C. and reverse voltages as high as about 50 V is less than about 10⁻⁶ A/cm² (e.g., less than about 8.0×10⁻⁷ A/cm², less than about 7.0×10⁻⁷ A/cm², less than about 6.0×10⁻⁷ A/cm²). The breakdown voltages at room temperature is greater than about 400 V and less than about 500 V (e.g., 400 V, 450 V).

Working examples, in accordance with some embodiments, are presented below, but it should be understood that the following descriptions are not intended to limit the scope of the invention, and are merely presented as illustrations. In the working examples that follow, bulk 4H—SiC with 8° miscut (towards a <1120> direction) (0001) Si-face wafers were coated with a TaC mask and patterned using standard photolithography. The TaC mask was formed by depositing about a 65 nm-thick Ta layer via evaporation, followed by patterning of mask openings, and by exposing the Ta to an ambient of about 1.5×10⁻⁴ mole fraction C3H8 in H₂ at a temperature of about 1300° C. for about 30 minutes. Selective epitaxial growth of SiC was carried out in a horizontal, rf-heated cold wall CVD reactor at temperatures in the range of about 1450° C. to about 1550° C. Flow rates were about 1.2 sccm, about 0.6 sccn to about 1.5 sccm, and about 9 slm for C3H8, SiH4, and H2, respectively. Epilayers were grown under a total reactor pressure of about 100 torr, which results in nominal planar growth rates of about 3 μm/hour to 4 μm/hour.

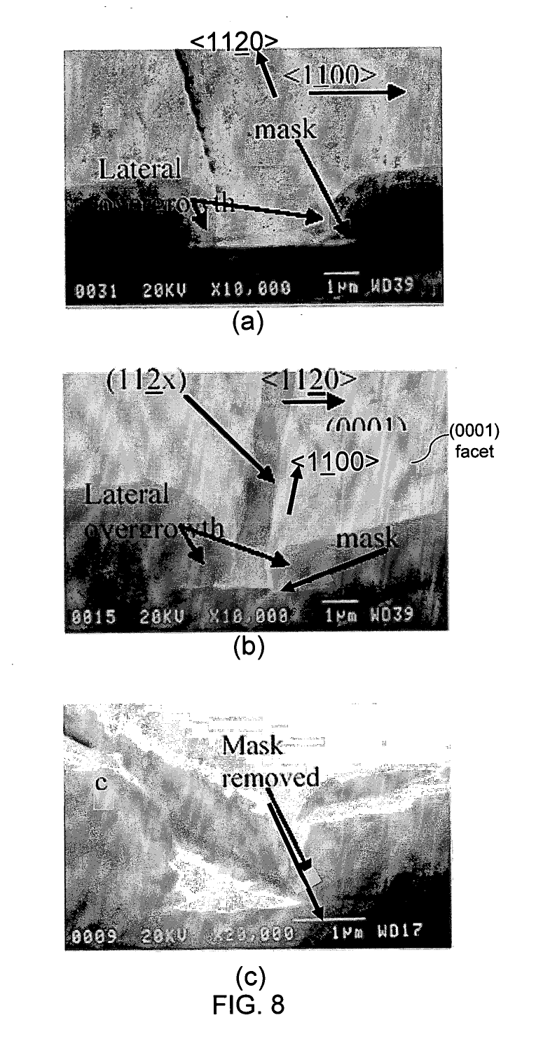

FIG. 8(a)-(c) are scanning electron microscopy (SEM) cross sectional views of illustrative working examples of SiC selectively grown using a TaC mask. The SEM views show structures resulting from the selective growth of SiC for (a) mask openings with sides along the <1120> miscut direction, and (a) mask openings with sides along the <1100> direction (i.e., where the <1100> direction is perpendicular to the miscut direction).

Growth features vary depending on whether the sides of the mask opening aligned are along one of the two principal directions, as shown in FIG. 8(a) and 8(b). When the sides of the mask openings are aligned along the <1120> miscut direction, the epitaxial growth on the exposed substrate area can conform to the substrate orientation, and the top surface may be smooth and specular, as shown in FIG. 8(a). When the sides of the mask openings are aligned along the <1100> direction (i.e., where the <1100> direction is perpendicular to the miscut direction), the epitaxial growth on the exposed substrate area can develop a (0001) surface facet, as shown in FIG. 8(b).

FIG. 8(a) and 8(b) also illustrate working examples of epitaxial lateral overgrowth over a TaC mask, where the extent of lateral growth can varies with the orientation of the sides of the mask openings. When the mask opening sides are along the <1100> direction, lateral overgrowth on the mask can extend about 1.8 μm at the mask opening side located at the downside of the <1120> direction, and about 1.4 μm at the mask opening side located at the upside of the <1120> direction, as shown in FIG. 8(b). When the mask opening side is along the <1120> direction, the lateral overgrowth can extend about 0.9 μm on both sides of the opening, as shown in FIG. 8(a). Therefore, in this working example, the anisotropic lateral growth rate is higher along the <1120> direction than along the <1100> direction.

Moreover, as previously described, the TaC mask can be removed (e.g., using a wet chemical etch), resulting in a structure illustrated in FIG. 8(c).

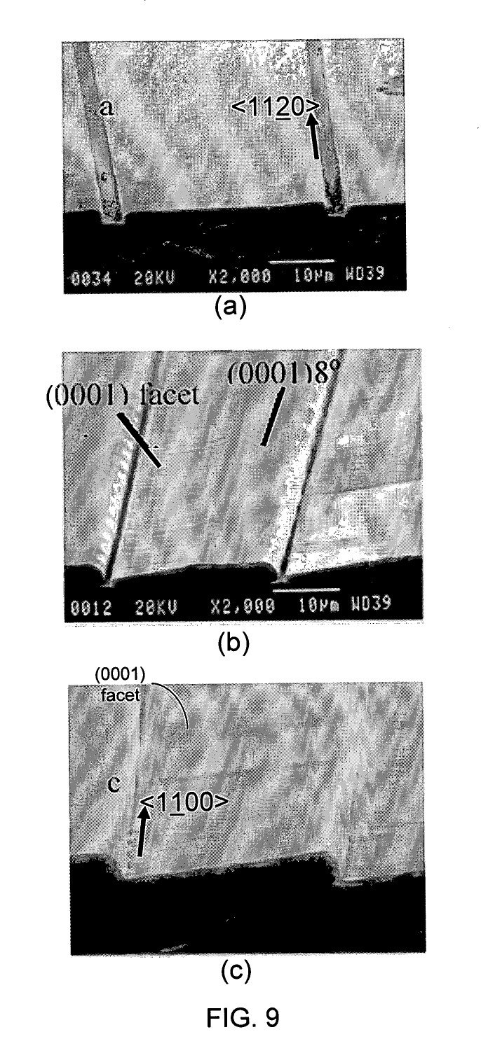

FIG. 9(a)-(c) are large-scale SEM views of illustrative working examples of SiC selectively grown using a TaC mask further showing the dependence of facet formation on the orientation of the mask opening sides. The SEM views show structures resulting from the selective growth of SiC for mask openings having sides (a) along the <1120>miscut direction, (b) along directions between <1120> and <1100>, and (c) along the <1100> direction.

As noted in connection with FIG. 8, when the mask openings have sides aligned along the <1120> miscut direction, the growth on the exposed substrate area conforms to the substrate orientation, and the top surface is smooth and specular, as further illustrated in FIG. 9(a). However, when the mask openings have sides aligned along <1100> direction, the selective epilayer develops a (0001) facet, as shown in FIG. 9(c). For mask openings with sides along other angles, a (0001) facet intersects the 8° off (0001) growth surface, and the extent of the (0001) facet depends on the angle between the sides of the mask opening and the <1120> miscut direction.

The (0001) facets may arise, in part, due to the substrate miscut. When the mask opening side direction is along the <1120> miscut direction, there may be no restriction on the step-flow growth, and new steps can be generated continuously and therefore a facet develops only at the ends. However, when the sides of the mask opening are along the <1100> direction (i.e., perpendicular to the <1120> miscut direction), step-flow can be restricted to within a 5 μm wide opening. For mask openings having sides aligned in directions between these two principal directions, the area of the opening occupied by the (0001) facet depends on the angle of the sides of the mask opening with respect to the <1120> miscut direction.

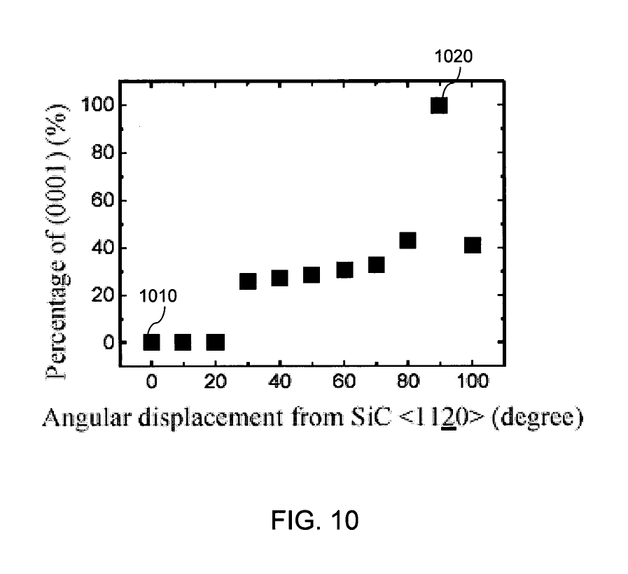

FIG. 10 is a graph of the percentage of the mask opening area occupied by the (0001) facet as a function of the orientation of the mask opening sides, for the illustrative working examples. The case where mask openings having sides aligned along the <1120> miscut direction correspond to the zero degree case, as indicated by data point 1010, whereas the case where mask openings having sides aligned along the <100> direction correspond to the 90 degree case, as indicated by data point 1020.

The percentage of the mask opening area occupied by the (0001) facet increases from 0% to 100% as the side of the mask opening varies so as to be aligned with the <1120> direction to the <1100> direction. As a result, in some embodiments, when selective growth is used for the formation of some devices structures, a mask opening with sides along the <1120> miscut direction may be preferred so as to ensure that substantially no (0001) facet growth area is present on the selectively grown epilayer.

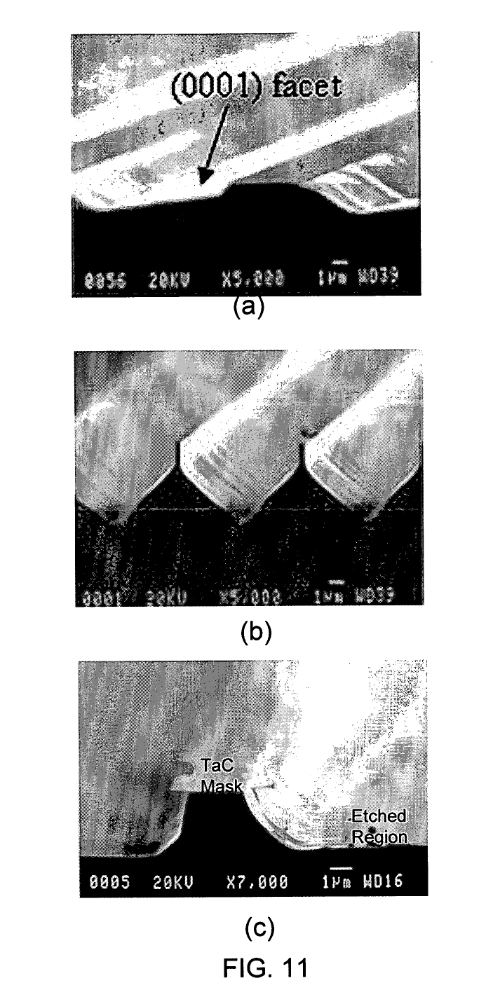

FIG. 11 shows cross sectional SEM views of SiC selectively etched using a TaC mask. Etched regions develop facets similar to the aforementioned selective growth working examples. When the sides of the mask opening are aligned along the <1100> direction, the bottom of the etched surface is oriented at 8° degrees with respect to the top surface, indicating that the bottom surface may be a (0001) facet, as shown in FIG. 11(a). However, when the sides of the mask opening are aligned along the <1120> miscut direction, the etched regions show no such asymmetry, as shown in FIG. 11(b).

Furthermore, the shape of the etched region depends on the width of the mask opening, as shown in FIG. 11(b) and FIG. 11(c).

As should be appreciated from the foregoing, at least some of the embodiments presented may be used in the fabrication of high voltage devices by selectively growing SiC-based semiconductors on suitable substrates (e.g., SiC substrates). Furthermore, some of the embodiments may be used to grow SiC (e.g., on SiC substrates) for use as substrates for the epitaxial growth of GaN. Also, some of the embodiments may facilitate the growth of SiC (e.g., on SiC substrates) for use as substrates to grow 3C—SiC, which may in turn aid in the fabrication of SiC-based devices (e.g., heterojunction devices).

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A method of selectively growing silicon carbide, comprising:
forming a mask comprising tantalum carbide that masks a portion of a substrate comprising silicon carbide to leave an exposed surface of the substrate; and
growing, epitaxially, a crystal comprising silicon carbide seeded by the exposed surface of the substrate.

2. The method of claim 1, wherein growing comprises causing the crystal to grow laterally over the mask.

3. The method of claim 1, wherein growing comprises growing at a temperature above about 1200° C.

4. The method of claim 1, wherein the mask comprises at least one opening with at least one side aligned substantially along a miscut direction of the substrate.

5. The method of claim 4, wherein the miscut direction of the substrate is a <1120> direction of the substrate.

6. The method of claim 1, wherein the mask comprises at least one opening with at least one side aligned substantially along a direction perpendicular to a miscut direction of the substrate.

7. The method of claim 6, wherein the direction perpendicular to the miscut direction of the substrate is a <1100> direction of the substrate.

8. The method of claim 1, further comprising epitaxially growing a semiconductor comprising gallium nitride over the crystal comprising silicon carbide.

9. The method of claim 1, further comprising removing the mask.

10. The method of claim 9, wherein removing the mask comprises etching the mask with a solution comprising nitric acid and hydrofluoric acid.

11. The method of claim 1, wherein the epitaxially grown crystal comprises epitaxially grown doped silicon carbide.

12. The method of claim 11, wherein the substrate comprises a doping having a polarity opposite the doping of the epitaxially grown doped silicon carbide.

13. The method of claim 12, further comprising forming a device comprising a p-n junction, wherein the p-n junction is formed at an interface of the substrate and the epitaxially grown doped silicon carbide.

14. The method of claim 13, wherein the device comprising the p-n junction comprises a p-n junction diode.

15. The method of claim 13, wherein the device comprising the p-n junction comprises a bipolar junction transistor.

16. A method of selectively etching silicon carbide, comprising:
forming a mask comprising tantalum carbide that masks a portion of a substrate comprising silicon carbide to leave an exposed surface of the substrate; and
etching the exposed surface of the substrate at a temperature above about 1200° C.

17. The method of claim 16, wherein the mask comprises at least one opening with at least one side aligned substantially along a miscut direction of the substrate.

18. The method of claim 17, wherein the miscut direction of the substrate is a <1120> direction of the substrate.

19. The method of claim 16, further comprising removing the mask.

20. The method of claim 19, wherein removing the mask comprises etching the mask with a solution comprising nitric acid and hydrofluoric acid.

21. A method of fabricating a device comprising:
forming a mask comprising tantalum carbide that masks a portion of a first layer of the device to leave an exposed surface of the first layer; and
growing, epitaxially, a second layer of the device, wherein the second layer comprises a crystal comprising silicon carbide seeded by the exposed surface of the first layer.

22. The method of claim 21, wherein the first layer of the device comprises a substrate.

23. The method of claim 22, wherein the substrate comprises a recessed surface region.

24. The method of claim 21, wherein the second layer of the device is doped.

25. The method of claim 24, wherein an interface between the first and second layer forms a p-n junction.

26. The method of claim 21, wherein growing comprises growing at a temperature above about 1200° C.

27. The method of claim 21, wherein the mask comprises at least one opening with at least one side aligned substantially along a miscut direction of the substrate.
